(19) United States
(12) Patent Application Publication
(10) Pub. No.: US 2003/0040161 A1
(43) Pub. Date: Feb. 27, 2003

(54) Method of producing an integrated component with a metal-insulator-metal capacitor

(76) Inventors: Michael Schrenk, Diessen Am Ammersee (DE); Markus Schwerd, Holzkirchen (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/237,230

(22) Filed: Sep. 3, 2002

Related U.S. Application Data
(63) Continuation of application No. PCT/EP01/01853, filed on Feb. 19, 2001.

(30) Foreign Application Priority Data
Mar. 1, 2000 (EP) 00104264.7

(51) Int. Cl. H01L 21/44; H01L 21/20

(52) U.S. Cl. 438/393; 438/687

(57) ABSTRACT

An integrated component with integrated metal-insulator-metal capacitor and copper-containing interconnects is produced by, first of all, depositing a dielectric interlayer and an upper electrode on a lower electrode, made from copper, over the entire surface. Then, the metal-insulator-metal capacitor is patterned. The etching stops at the dielectric interlayer, which serves as an etch stop. This avoids short circuits between the upper electrode and the lower electrode.

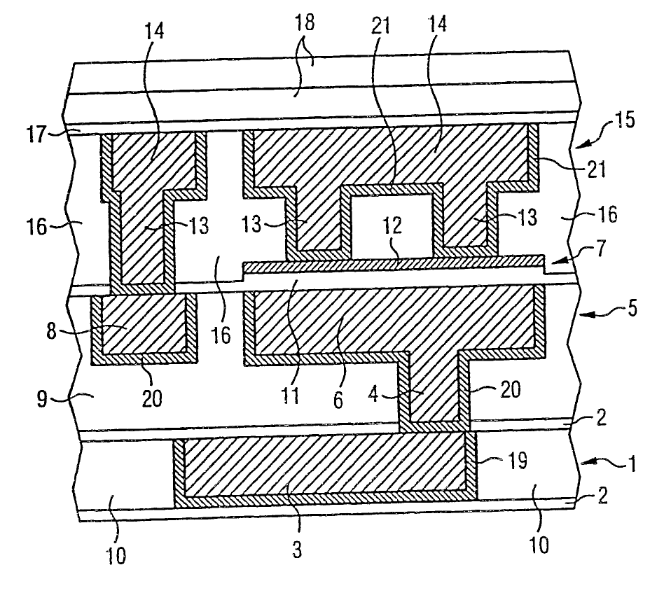

### CROSS-REFERENCE TO RELATED APPLICATION

This application is a continuation of copending International Application No. PCT/EP01/01853, filed Feb. 19, 2001, which designated the United States and which was not published in English.

### BACKGROUND OF THE INVENTION

Field of the Invention

The invention lies in the integrated technology field. More specifically, the invention relates to an integrated component and a method of producing such an integrated component with interconnects made from a copper-containing alloy and a metal-insulator-metal capacitor.

High-frequency circuits used in the BIPOLAR, BICMOS and CMOS technologies require integrated capacitors with a high voltage linearity, capacitances which can be set accurately, and in particular small parasitic capacitances. Voltage-induced space charge regions that have been provided in conventional MOS capacitors exhibit insufficient voltage linearity. Moreover, the short distance from the substrate entails numerous parasitic capacitances. These difficulties can be avoided by using so-called metal-insulator-metal capacitors (MIM capacitors). These metal-insulator-metal capacitors should as far as possible be integrated in the existing concepts for multilayer metalization, without changing and influencing the adjacent interconnects.

Currently, there does not exist any known process for integrating metal-insulator-metal capacitors in integrated components with copper-containing interconnects.

### SUMMARY OF THE INVENTION

It is accordingly an object of the invention to provide an integrated component with a metal-insulator-metal capacitor and a fabrication method which overcome the above-mentioned disadvantages of the heretofore-known devices and methods of this general type and which provides for a method of fabricating an integrated component having interconnects made from a copper-containing alloy and an integrated metal-insulator-metal capacitor.

With the foregoing and other objects in view there is provided, in accordance with the invention, a method for fabricating an integrated component with copper-containing interconnects and a metal-insulator-metal capacitor, which comprises the following steps:

forming an embedded first electrode in an interlayer dielectric with a damascene process;

depositing a dielectric interlayer and then a metalization layer over an entire surface above the first electrode;

patterning the metalization layer and thereby using the dielectric interlayer as an etching stop, to form a patterned metalization layer; and

applying a protective layer of silicon nitride to the patterned metalization layer and the dielectric interlayer.

In accordance with an added feature of the invention, the dielectric interlayer additionally serves as a diffusion barrier.

In accordance with an additional feature of the invention, the metalization layer is formed as a stack of metal layers and conductive barriers.

In accordance with another feature of the invention, the metalization layer contains at least one metal from the group Al, Si, W, Cu, Au, Ag, Ti, and Pt.

In accordance with a further feature of the invention, the interconnects and the first electrode are delimited by barriers with respect to an interlayer dielectric.

In accordance with again an added feature of the invention, the barriers are formed from elements selected from the group Ta, TaN, TiW, W, WNₓ, Ti, TiN, or silicides, where 0≦x≦2.

The dielectric interlayer can be formed of SiO₂ or Si₃N₄. Preferably, it is formed of a dielectric material with a dielectric constant of >80.

In accordance with a concomitant feature of the invention, the dielectric interlayer is fabricated from Ta₂O₅, Bi₂Sr₃TiO₃, or BaₓSr₁₋ₓTiO₃, where 0≦x≦1.

The metal-insulator-metal capacitor has an electrode which is formed in a metal plane for interconnects. Since the dielectric interlayer and the metalization layer can be kept thin, the metal-insulator-metal capacitor can be integrated in an existing concept for fabrication of an integrated component with passive components without major difficulties.

In the fabrication of the metal-insulator-metal capacitor, the dielectric interlayer expediently serves as an etching stop. This ensures that the copper-containing electrodes below it are not attacked by the etching medium. Since, moreover, the dielectric interlayer which serves as a etching stop is not completely removed, short circuits between the metalization layer and the electrode below it are avoided.

It is expedient for the metal-insulator-metal capacitor to be fabricated by first of all depositing a dielectric interlayer, which serves as an etching stop, and then a metalization layer on the uncovered electrode in the metal level for interconnects, over the entire surface. During the subsequent patterning of the metalization layer, the dielectric interlayer serves as an etching stop and therefore is retained substantially over the entire surface. This effectively suppresses short circuits at the edges of the metal-insulator-metal capacitor.

Other features which are considered as characteristic for the invention are set forth in the appended claims.

Although the invention is illustrated and described herein as embodied in a method of producing an integrated component with a metal-insulator-metal capacitor, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawing.

### BRIEF DESCRIPTION OF THE DRAWINGS

The sole FIGURE of the drawing is a partial cross section through an integrated component with an integrated-metal-insulator-metal capacitor.

### DESCRIPTION OF THE PREFERRED EMBODIMENTS

Referring now to the FIGURE of the drawing in detail, there is illustrated a section through the layers which usually contain the passive components of an integrated circuit. In a first metal level 1, interconnects 3 are arranged between nonconductive diffusion barriers 2. The interconnect 3 is connected to a lower electrode 6, arranged in a second metal level 5, of a metal-insulator-metal capacitor 7 through a via 4. In the excerpt illustrated in the FIGURE there is shown, next to the lower electrode 6, a further interconnect 8 in the metal level 5. The interconnect 8 and the lower electrode 6 are embedded in an interlayer dielectric 9. This is expediently the same material which, as separating dielectric 10 in the metal level 1, insulates the interconnects 3 from one another. A dielectric interlayer 11 is applied to the lower electrode 6, and on the dielectric interlayer 11 there is a metalization layer, which forms the upper electrode 12. In the region of the metal-insulator-metal capacitor 7, the dielectric interlayer 11 has a greater thickness than outside the metal-insulator-metal capacitor 7 and extends over the entire surface of the interlayer dielectric 9.

The upper electrode 12 of the metal-insulator-metal-capacitor 7 and the interconnect 3 are connected to interconnects 14 in a third metal level 15 through vias 13. The upper electrode 12, the vias 13 and the interconnects 14 in the third metal level 15 are located in an interlayer dielectric 16. Finally, above the third metal level 15 there is provided a further nonconductive diffusion barrier 17 and further covering layers 18.

The interconnects 3, 8 and 14, the lower electrode 5 and the vias 4 and 13 are made from a copper-containing alloy. Preferably, they are formed from pure copper. A so-called damascene process is used to fabricate the interconnects 3, 8 and 14, the lower electrode 6 and the vias 4 and 13.

In particular, the dual damascene process is used to fabricate the interconnects 8 and 14, the lower electrode 6 and the vias 4 and 13.

In the damascene process, by way of example first of all the separating dielectric 10 is deposited over the entire surface of the diffusion barrier 2 resting on a substrate. In this context, the term substrate is understood as meaning both a homogenous base body and a base body with a layered structure. Then, trenches which are provided for the interconnects 3 are etched into the separating dielectric 10. Finally, the trenches are lined with a conductive barrier 19 by conformal deposition. In a subsequent electrolysis step, the barrier 19 serves as an electrode for deposition of the copper for the interconnect 3.

As mentioned above, the interconnects 8, the lower electrodes 6 and the vias 4 are fabricated using the dual damascene process. For this purpose, first of all the interlayer dielectric 9 is deposited over the entire surface of the diffusion barrier 2. Then, trenches for the interconnect 8 and the lower electrode 6 are etched out of the interlayer dielectric 9. In a further etching operation, these trenches are recessed further at the locations at which the vias 4 are provided. Then, the recesses formed in this way are provided with a barrier 20 by conformal deposition. Then, the deposited copper accumulates at the barrier 19, which serves as an electrode, during the subsequent electrolysis.

Finally, the dielectric interlayer 11 and the metalization layer provided for the upper electrode 12 are deposited over the entire planarized surface. The metalization layer provided for the upper electrode 12 may be a homogeneous layer of an alloy or a stack of metal layers and conductive barriers. Then, the metal-insulator-metal capacitor 7 is patterned, with an etching stop in the dielectric interlayer 11. Therefore, the dielectric interlayer 11 is retained even outside the metal-insulator-metal capacitor 7. The extensive electrical separation of upper electrode 12 and lower electrode 6 means that there is no risk of short circuit between the lower electrode 6 and the upper electrode 12. A further advantage is that the dielectric interlayer 11 and the upper electrode 12 can be applied to a planarized surface. This ensures the planarity of the dielectric interlayer 11 and of the upper electrode 12.

Following the formation of the metal-insulator-metal capacitor 7, the interlayer dielectric 16 is deposited. Then, the interconnect 14 and the vias 13 are formed using the dual damascene process. Barriers 21 adopt the role of the electrodes required for deposition of the copper. When the trenches for the vias 13 are being etched out, the etching should stop simultaneously at the upper electrode 12 of the metal-insulator-metal capacitor 7 and the interconnects 14.

An example of a suitable material of the dielectric interlayer 11 is Si₃N₄ or SiO₂. Furthermore, the materials with a high dielectric constant, such as Ta₂O₅ or Bi₂Sr₃TiO₃ and BaₓSr₁₋ₓTiO₃, where 0≦x≦1, are suitable for the dielectric interlayer 11. It is particularly advantageous that the etching characteristics of these materials do not have to be known individually, because of the etching stops in the middle of the dielectric interlayer 11. Ta, TaN, as well as silicides and materials such as Ti, TiN, TiW, W and WNₓ, where 0≦x≦2, are suitable for the upper electrode 12. Furthermore, conductive materials, such as Si, W, Cu, Au, Ag, Ti and Pt and alloys thereof, can be used for the upper electrode 12.

In a modified exemplary embodiment, which is not illustrated in the drawing, the upper electrode 12 and the dielectric interlayer 11 are covered by a protective layer of SiN. This protective layer serves as a stop for the etching of the vias 13 and prevents the upper electrode 12 from being attacked during the etching of the vias 13. Moreover, the upper electrode 12 is encapsulated to the side and in this way is additionally insulated with respect to the lower electrode 6.

Finally, it should be noted that the proposed integrated component is suitable in particular for use in high-frequency technology.

We claim:

1. A method for fabricating an integrated component with copper-containing interconnects and a metal-insulator-metal capacitor, which comprises the following steps:
forming an embedded first electrode in an interlayer dielectric with a damascene process;
depositing a dielectric interlayer and then a metalization layer over an entire surface above the first electrode;
patterning the metalization layer and thereby using the dielectric interlayer as an etching stop, to form a patterned metalization layer; and
applying a protective layer of silicon nitride to the patterned metalization layer and the dielectric interlayer.

2. The method according to claim 1, wherein the dielectric interlayer additionally serves as a diffusion barrier.

3. The method according to claim 1, which comprises forming the metalization layer as a stack of metal layers and conductive barriers.

4. The method according to claim 1, which comprises forming the metalization layer to contain at least one metal selected from the group consisting of Al, Si, W, Cu, Au, Ag, Ti, and Pt.

5. The method according to claim 1, which comprises delimiting the interconnects and the first electrode by barriers with respect to an interlayer dielectric.

6. The method according to claim 5, which comprises fabricating the barriers from elements selected from the group consisting of Ta, TaN, TiW, W, WNₓ, Ti, TiN, and silicides, where 0≦x≦2.

7. The method according to claim 1, which comprises producing the dielectric interlayer from a silicon compound selected from the group consisting of SiO₂ and Si₃N₄.

8. The method according to claim 1, which comprises producing the dielectric interlayer from a dielectric material with a dielectric constant of >80.

9. The method according to claim 8, which comprises fabricating the dielectric interlayer from a material selected from the group consisting of Ta₂O₅, Bi₂Sr₃TiO₃, and BaₓSr₁₋ₓTiO₃, where 0≦x≦1.

10. The method according to claim 1, which comprises forming the integrated component with interconnects of a copper alloy.

11. The method according to claim 1, which comprises forming the integrated component with interconnects of pure copper.
